(19) United States
(12) Patent Application Publication
(10) Pub. No.: US 2024/0429265 A1
(43) Pub. Date: Dec. 26, 2024

(54) TRANSFORMER-BASED ISOLATOR WITH SPIRAL COILS

(71) Applicant: Allegro MicroSystems, LLC, Manchester, NH (US)

(72) Inventor: William P. Taylor, Amherst, NH (US)

(73) Assignee: Allegro MicroSystems, LLC, Manchester, NH (US)

(21) Appl. No.: 18/338,479

(22) Filed: Jun. 21, 2023

(51) Int. Cl. H01L 27/08; H01F 27/28; H01F 41/04

(52) U.S. Cl. CPC H01L 28/10; H01F 27/2804; H01F 41/041; H01F 2027/2809

(57) ABSTRACT

Aspects of the present disclosure include systems, structures, circuits, and methods providing integrated circuit (IC) packages or modules having a transformer with first and second spiral coils disposed on or adjacent to a substrate, each including one or more coil portions on one or multiple levels and having varying distances to an aperture or coil-origin region. A portion of a soft ferromagnetic core of the transformer can pass through the aperture or be adjacent to the coil origin region. The IC packages and modules may include various types of circuits; in some examples, IC packages or modules may include a galvanically isolated gate driver or other high voltage circuit.

### BACKGROUND

Solid state switches typically include a transistor structure that is usually either turned on or turned off in operation. The controlling electrode of the switch, usually referred to as its gate (or base), is typically controlled (driven) by a switch drive circuit, sometimes also referred to as gate drive circuit or driver. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Galvanic isolation can be used to separate circuits in order to protect users from coming into direct contact with hazardous voltages, which can be present for high-power solid state switches.

Various transmission techniques are available for signals to be sent across galvanic isolation barriers including optical, capacitive, and magnetic coupling techniques. Magnetic coupling typically relies on the use of a transformer to magnetically couple circuits on the different sides of the transformer, typically referred to as the primary and secondary sides, while also providing galvanic separation of the circuits.

Transformers used for magnetic coupling across isolation barriers may utilize a magnetic core to provide a magnetic path to channel flux created by the currents flowing in the primary and secondary sides of the transformer. Magnetic-coupling across galvanic isolation barriers has been shown to have various drawbacks, including manufacturing problems, for integrated circuit (IC) packages due to the included magnetic core.

### SUMMARY

One general aspect of the present disclosure includes a voltage-isolated integrated circuit (IC) package having one or more spiral coils. The voltage-isolated integrated circuit package can include a substrate including an aperture; first and second semiconductor die disposed on the substrate; first and second lead sets connected to the first and second semiconductor die, respectively; a transformer configured to provide magnetic coupling and galvanic separation between the first and second semiconductor die; and a mold material forming a package body and configured to cover a portion or all of the transformer, where the package body includes a plurality of apertures exposing portions of the first and second lead sets. The transformer can include a first coil disposed on a first surface of the substrate and coupled to the first semiconductor die. The first coil can have a first coil portion on a first level with respect to the first surface of the substrate and can include a path from a location distal to the aperture to a location adjacent the aperture. The first coil portion can have a decreasing radial distance to the aperture along the path, where the path of the first coil portion extends around the aperture. The transformer can include a second coil disposed on a second surface of the substrate and can be coupled to the second semiconductor die. The second coil can have a first coil portion on a first level with respect to the second surface of the substrate and can include a path from a location distal to the aperture to a location adjacent the aperture. The first coil portion of the second coil can have a decreasing radial distance to the aperture along the path, where the path of the first coil portion extends around the aperture. The transformer can include a soft ferromagnetic core that can have one or more portions disposed adjacent to the first coil and/or second coil and/or in or through the aperture in the substrate.

Implementations may include one or more of the following features. A portion of the magnetic core of the voltage-isolated IC package may be disposed through the aperture in the substrate. A portion of the core may be disposed on a side of the first coil distal to the substrate. A portion of the core may be disposed on a side of the second coil distal to the substrate. The first coil may include a second coil portion on a second level with respect to the first surface of the substrate and can include a path from the location adjacent the aperture to the location distal to the aperture (e.g., at a conductive connection to the first semiconductor die), the second coil portion having an increasing radial distance to the aperture along the path, where the second coil portion is connected to the first coil portion, and where the path of the second coil portion extends around the aperture. The second coil may have a second coil portion on a second level with respect to the second surface of the substrate and can include a path from the location adjacent the aperture to the position distal to the aperture (e.g., at a conductive connection to the second semiconductor die), the second portion having an increasing radial distance to the aperture along the path, where the second coil portion is connected to the first coil portion, and where the path of the second coil portion extends around the aperture. The first and/or second coil may include one or more elliptical windings. The first and/or second coil may include one or more circular windings. The first and/or second coil may include one or more rectangular windings. The first and/or second coil may include one or more square-like windings. The substrate may include a flexible substrate. The substrate may include a printed circuit board (PCB). The substrate may include a low-temperature cofired ceramic (LTCC) or a high-temperature cofired ceramic (HTCC). The substrate may include an alumina substrate. The substrate may include a glass substrate having one or more layers (composite or “sandwich” structure) of metal and insulator material. The substrate may include a lead frame. The lead frame may include a molded lead frame. The voltage-isolated IC package may include a dielectric material covering a portion of the transformer, first coil, and/or second coil. The dielectric material may include a gel. A shortest distance between first and second voltage regions of primary and secondary sides of the transformer, respectively, may be or may be at least 1 mm. A shortest distance between first and second voltage regions of primary and secondary sides of the transformer, respectively, may be or may be at least 1.2 mm. A shortest distance between first and second voltage regions of primary and secondary sides of the transformer, respectively, may be or may be at least 1.5 mm. A shortest distance between first and second voltage regions of primary and secondary sides of the transformer, respectively, may be or may be at least 3 mm. A shortest distance between first and second voltage regions of primary and secondary sides of the transformer, respectively, may be or may be at least 5.5 mm. A shortest distance between first and second voltage regions of primary and secondary sides of the transformer, respectively, may be or may be at least 7.2 mm. A shortest distance between exposed portions of the first and second lead sets, respectively, may be or may be at least 8 mm (or a greater distance, e.g., 10 mm, or 10+mm). The first or second semiconductor die may include a gate driver in some embodiments.

One general aspect of the present disclosure includes a method of making a voltage-isolated integrated circuit (IC) package. The method can include providing a substrate configured to receive or support (directly or indirectly) one or more semiconductor (IC) die. The substrate can include an aperture or a coil origin region. The method can include providing a portion of a transformer core in the aperture or adjacent to the coil origin region. The method can include providing first and second semiconductor die disposed on the substrate. The method can include providing a first coil disposed on a first surface of the substrate and coupled to the first semiconductor die, where the first coil has a first coil portion on a first level with respect to the first surface of the substrate, the first coil portion including a path from a location distal to the aperture or coil origin region to a location adjacent the aperture or coil origin region and having a decreasing radial distance to the aperture or coil origin region along the path. The method can include providing a second coil disposed on a second surface of the substrate and coupled to the second semiconductor die, where the second coil has a first coil portion on a first level with respect to the second surface of the substrate, the first coil portion including a path from a location distal to the aperture or coil origin region to a location adjacent the aperture or coil origin region and having a decreasing radial distance to the aperture or coil origin region along the path.

Implementations may include one or more of the following features. The method may include, for the first coil, providing a second coil portion on a second level with respect to the first surface of the substrate, the second coil portion including a path from the location adjacent (near to) the aperture or coil origin region to the location distal to the aperture or coil origin region. The second coil portion of the first coil can have an increasing radial distance to the aperture or coil origin region along the path. The first coil portion of the first coil can be connected to the second coil portion. The method may include connecting the first coil portion of the first coil to the second coil portion by a via. The method may include, for the second coil, providing a second coil portion on a second level with respect to the second surface of the substrate, the second coil portion including a path from the location adjacent (near to) the aperture or coil origin region to the location distal to the aperture or coil origin region. The second coil portion of the second coil can have an increasing radial distance to the aperture or coil origin region along the path. The first coil portion of the second coil can be connected to the second coil portion. The method may include connecting the first coil portion of the second coil to the second coil portion by a via. The first and second coils and the transformer core can be configured as a transformer (e.g., having a step up, a step down, or a power transformer configuration) for magnetically coupling the first semiconductor die to the second semiconductor die. The substrate may include a flexible substrate. The substrate may include a printed circuit board (PCB). The substrate may include a low-temperature cofired ceramic (LTCC) or a high-temperature cofired ceramic (HTCC). The substrate may include an alumina substrate. The substrate may include a glass substrate having one or more layers (composite or “sandwich” structure) of metal and insulator material. The substrate may include a lead frame. The lead frame may include a molded lead frame.

One general aspect of the present disclosure includes a voltage-isolated integrated circuit (IC) package. The IC package can include a substrate, e.g., configured to receive or support one or more semiconductor die. The substrate may include an aperture or coil origin region. The IC package may include one or more semiconductor die, e.g., first and second die, which may be disposed on (directly or indirectly) or supported by the substrate. One or more lead sets may be configured for connection to the one or more semiconductor die, respectively. The IC package may include a transformer configured to provide magnetic coupling and galvanic separation for circuitry including the one or more semiconductor die. The transformer may have: a first spiral coil disposed on a first level with respect to the substrate and extending around the aperture or coil origin region; a second spiral coil disposed on a second level with respect to the substrate and extending around the aperture or coil origin region; and a soft ferromagnetic core having a portion disposed through/adjacent the aperture or adjacent the coil origin region. The IC package may include a package body configured to cover a portion of the substrate, the ferromagnetic core, and the first and second spiral coils. The package body may include a plurality of apertures exposing portions of the one or more lead sets. In some embodiments, a coil origin region may be on any layer of a coil or coil portion and coil origin regions may differ among coils or coil portions.

Implementations may include one or more of the following features. For example, the first spiral coil of the voltage-isolated IC package may include a first coil portion disposed on the first level, the first coil portion including a path from a location distal to the aperture or coil origin region to a location adjacent the aperture or coil origin region and having a decreasing radial distance to the aperture or coil origin region along the path. The first spiral coil may further include a second coil portion disposed on a different level than that of the first coil portion (e.g., a third level) with respect to the substrate, the second coil portion including a path from the location adjacent the aperture or coil origin region to the position distal to the aperture or coil origin region. The second coil portion may have an increasing radial distance to the aperture or coil origin region along the path. The second coil portion may be connected to the first coil portion of the first spiral coil, e.g., by a via or other conductive structure. The second spiral coil may include a first coil portion disposed on the second level, the first coil portion including a path from a location distal to the aperture or coil origin region to a location adjacent the aperture or coil origin region and having a decreasing radial distance to the aperture along the path. The second spiral coil may include a second coil portion on a different level than that of the first coil portion (e.g., on a fourth level) with respect to the substrate. The second coil portion of the second coil may include a path from the location adjacent (near to) the aperture or coil origin region to the position distal to the aperture or coil origin region and may have an increasing radial distance to the aperture or coil origin region along the path. The second coil portion may be connected to the first coil portion of the second spiral coil, e.g., by a via or other conductive structure.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed examples and embodiments of the present disclose may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, examples and embodiments are illustrated by way of example and not limitation in the figures, in which:

FIGS. 1A-1B show side and top views, respectively, of an example transformer-based isolator with multi-level spiral coils, in accordance with the present disclosure;

FIGS. 2A-2B show side and top views, respectively, of another example transformer-based isolator with multi-level spiral coils, in accordance with the present disclosure;

FIGS. 3A-3B show side and top views, respectively, of another example transformer-based isolator with multi-level coils, in accordance with the present disclosure;

FIG. 4 is a block diagram showing steps in an example fabrication method for a transformer-based isolator with multi-level coils, in accordance with the present disclosure; and

FIG. 5 shows a side view of an example IC package having a transformer-based isolator with multi-level spiral coils, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing transformers having single or multi-level spiral coils (or coil portions) that have segments with varying (direct or radial) distance to a structure or location of the transformer, e.g., an aperture or coil origin region of a substrate or a portion of a core of the transformer. In some embodiments, a transformer with one or more spiral coils or coil portions may have, e.g., a step up, a step down, or a power transformer configuration. The spiral coils may be connected to circuitry that includes one or more semiconductor (IC) die (a semiconductor “die” may be referred to in the plural as die, dies, or dice).

Examples and embodiments can include integrated circuit (IC) packages or modules with a voltage-isolation transformer. Examples and embodiments can include circuitry for data transmitters and receivers for data communication across a transformer-based isolation barrier and/or power transmission across the isolation barrier through a transformer. The IC packages and modules may include various types of circuits; in some examples, IC packages or modules may include a galvanically isolated gate driver or other high voltage circuit, etc. An IC package may include one or more (e.g., first and second) semiconductor die (dice), a.k.a., integrated circuit (IC) die with one or more ICs. Such integrated circuits (ICs) may include, but are not limited to, high-voltage circuits such as galvanically isolated gate drivers configured to drive an external gate on a MOSFET, a GaNFET, SiCFET, or another high-power solid-state switch. In some embodiments and examples, multiple die and transformers may be constructed into a single package.

Embodiments and examples of isolators and packages according to the present disclosure can be configured/implemented to meet a given voltage isolation requirement, including creepage and/or voltage breakdown requirements for a given pollution degree rating as defined by certain safety standards bodies such as the UL (Underwriters Laboratories), DIN (Deutsches Institut für Normung), ISO (International Organization for Standardization), VDA (Verband der Automobilindustrie) and/or the IEC (International Electrotechnical Commission), among others.

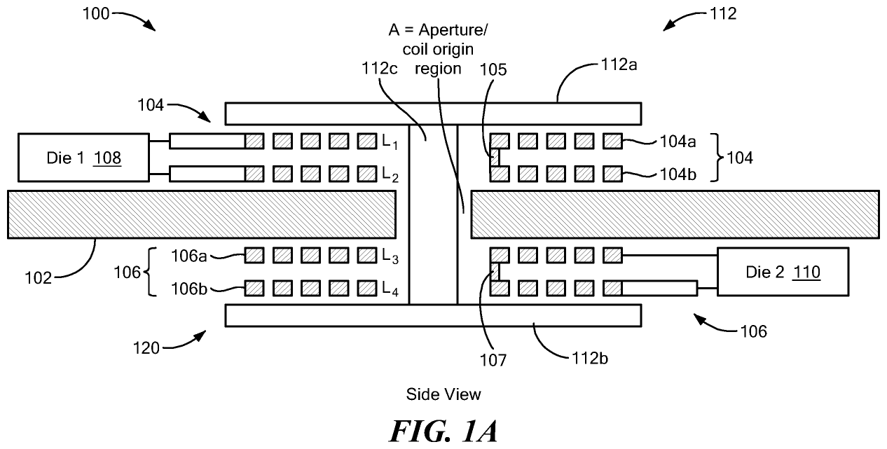

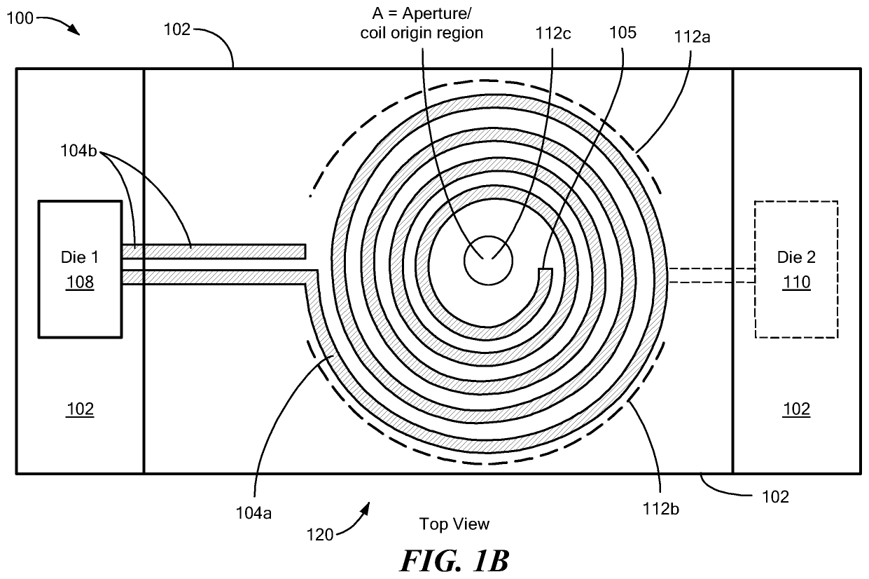

FIGS. 1A-1B show side and top views, respectively, of an example transformer-based isolator 100 with multi-level spiral coils, in accordance with the present disclosure. Isolator 100 can include substrate 102 and first and second coils 104, 106, as shown. Coils 104, 106 can be configured for coupled operation as a transformer 120 in conjunction with magnetic core 112. Substrate 102 is configured to receive/support first and second semiconductor die (a.k.a., IC dice or IC dies) 108 and 110 labeled as “Die 1” and “Die 2,” respectively. Die 108 and die 110 are shown disposed on opposite sides of substrate 102. In some embodiments, substrate 102 may have an aperture, A, configured to receive a portion of transformer core (core) 112. Core 112 is shown having first and second outer portions 112a-b and central portion 112c. Central core portion 112c is shown passing through substrate aperture A. In some embodiments outer core portions 112a-b may have disc shapes while central core portion 112c may have a cylindrical shape; other shapes are possible within the scope of the present disclosure, such as but not limited to rectangular/square shapes, hexagon shapes, and octagon shapes, etc. In some embodiments, e.g., where central core portion 112c is absent, substrate 102 may include a coil origin region (A), in which case(s), an aperture may or may not be present for substrate 102. First and second coils 104, 106 may be connected to first and second IC die 108, 110, as shown. Coils 104, 106 may be connected to die 108, 110 by any suitable connections, e.g., with wire bonds, or with a flip-chip process between the die 108, 110 and conductive traces on substrate 102 and wire bonds from the substrate to the transformer. First and second coils 104, 106 and first and second IC die 108, 110 along with connecting conductive structure can form primary (input) and secondary (output) sides, respectively, of transformer 120. In some embodiments and examples, the secondary side may be a high voltage side, e.g., with transformer 120 configured as a step up transformer.

In some embodiments and examples, a spiral coil may have a rough elliptical or polygonal nature or shape where successive/sequential adjacent smooth or straight segments (e.g., “turns”) of the spiral coil, in general, have a shorter distance, or radius, from a position/location on the segment to a position/location inside of or interior to the coil (e.g., a location at or near the geometric center or centroid) along the path of the coil from an outer (radial) position to an inner (radial) position; and, vice versa for the opposite direction of travel along the path of the coil (or coil portion). Example coil geometries can include, but are not limited to, polygonal geometries such as rectangular and square-like spirals. A square-like spiral coil geometry has four sides with the coil path being stepped inward on at least one side of a square as the distance to the center or middle of the “spiral” decreases. A spiral coil having an elliptical geometry can have any suitable eccentricity value (e), e.g., e=2.0, 1.8, 1.5, 1.2, or 1.0 (with eccentricity, e=1, being circular). Other shapes are possible for coils and coil portions within the scope of the present disclosure, such as a hexagon shaped spiral, an octagon shaped spiral, or a logarithmic spiral, etc. In some examples and/or embodiments, the first and second coils 104, 106 may have different coil geometries. In some examples and/or embodiments, first and second portions of a coil, e.g., coil portions 104a-b, may have different coil geometries. For example, a first spiral coil with two portions may have a square-like geometry for a first coil portion and a logarithmic spiral geometry for a second coil portion.

First and second coils 104, 106 may have portions on different levels, e.g., with respect to a surface of substrate 102 as shown by first coil portions 104a-b and second coil portions 106a-b, respectively. In some embodiments, first coil portions 104a-b may be formed or placed at different layers of a multilayer structure, e.g., PCB, flexible substrate (which may include a polymer, in one example a polyimide material, and multiple metal layer construction), or ceramic substrate, etc. Likewise, in some embodiments second coil portions 106a-b may be formed or placed at different layers of a multilayer structure, e.g., PCB, flexible substrate, or ceramic substrate, etc. As shown in FIG. 1B, first coil portion 104a may traverse a path on one level (surface), from a position distal to aperture A to a position adjacent to aperture A, with the path spiraling around aperture A. First coil portion 104a on one level (e.g., first level, L₁) can be connected, at via (conductive through hole) 105, to first coil portion 104b on a different level (e.g., second level, L₂), as shown in FIG. 1A. Similarly, second coil portion 106a may traverse a path on one level (surface), from a position distal to aperture A to a position adjacent to aperture A, with the path spiraling around aperture A. Second coil portion 106a on one level (e.g., third level, L₃) can be connected, at via (conductive through hole) 107, to second coil portion 106b on a different level (e.g., fourth level, L₄), as shown in FIG. 1A. As shown, first coil portions 104a-b of first coil 104 are on one side of substrate 102 while second coil portions 106a-b of second coil 106 are on the other side of substrate 102. In other examples and/or embodiments, first coil portions 104a-b of first coil 104 and second coil portions 106a-b of second coil 106 can be the same side of substrate 102, with one or more separation (e.g., insulator) layers disposed/interposed between coil 104 (104a-b) and 106 (106a-b).

In some examples and/or embodiments, 102 substrate may have one or more polymer or insulation layers (not shown), e.g., between the substrate 102 and an IC die 108, to comply or facilitate compliance with given voltage isolation requirements. In some examples, substrate 102 can include or be made of, e.g., a printed circuit board (PCB), flexible substrate, an alumina substrate, a co-fired ceramic (low-temperature or high-temperature) substrate, a lead frame, or a glass substrate including multiple thin layers.

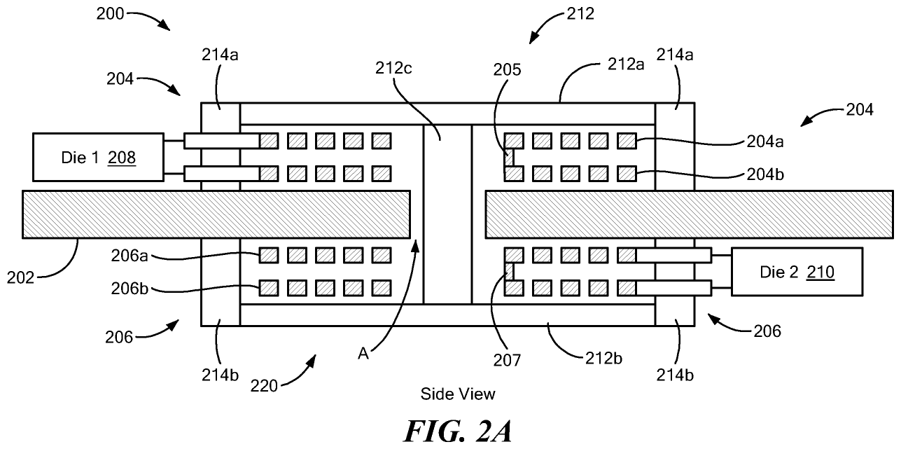

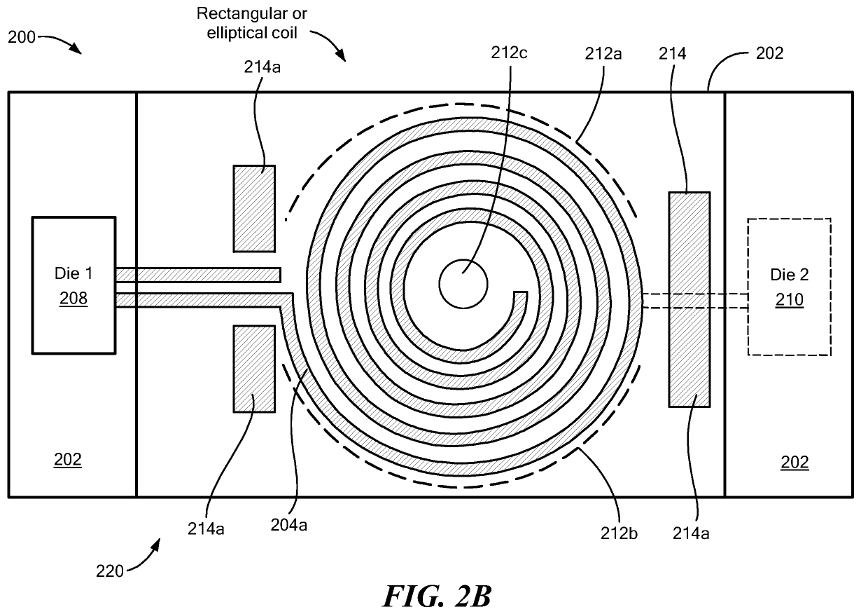

FIGS. 2A-2B show side and top views, respectively, of another example transformer-based isolator 200 with multi-level spiral coils, in accordance with the present disclosure. Isolator 200 can include substrate 202 and first and second coils 204, 206, as shown. Substrate 202 is configured to receive/support first and second semiconductor die 208 and 210. Die 208 (“Die 1”) and 210 (“Die 2) are shown disposed on opposite sides of substrate 202. Substrate 202 may have an aperture, A, configured to receive a portion of a transformer core (core) 212. Coils 204, 206 can be configured for coupled operation as a transformer 220 in conjunction with core 212. Core 212 is shown having first and second outer portions 212a-b and central portion 212c. Central core portion 212c is shown passing through substrate aperture A. In some examples and/or embodiments, outer core portions 212a-b may have disc shapes while central core portion 212c may have a cylindrical shape; other shapes are possible within the scope of the present disclosure. First and second coils 204, 206 may be connected to first and second IC die 208, 210, as shown. Core 212 can also include side (lateral) portions 214a-b, as shown in FIGS. 2A-2B. In other examples and embodiments, the side (lateral) core portions 214a-b may extend through the substrate 202 (similar to as shown for 212c), or partially through/into the substrate 202 to reduce the reluctance along the path(s) of the magnetic flux and make the transformer 220 more efficient.

First and second coils 204, 206 are shown having portions on different levels, e.g., first coil portions 204a-b and second coil portions 206a-b, respectively. In some embodiments, first coil portions 204a-b may be formed or placed at different layers of a multilayer structure, e.g., PCB or ceramic substrate, etc. Likewise, in some embodiments second coil portions 206a-b may be formed or placed at different layers of a multilayer structure, e.g., PCB or ceramic substrate, etc. As shown in FIG. 2B, first coil portion 204a may traverse a path on one level (surface) from a position distal to aperture A to a position adjacent to aperture A, with the path spiraling around aperture A. At via (through hole) 205 first coil portion 204a on one level can be connected to first coil portion 204b on a different level, as shown in FIG. 2A. Similarly, second coil portion 206a may traverse a path on one level (surface) from a position distal to aperture A to a position adjacent to aperture A, with the path spiraling around aperture A. At via (through hole) 207 second coil portion 206a on one level is connected to second coil portion 206b on a different level, as shown in FIG. 2A.

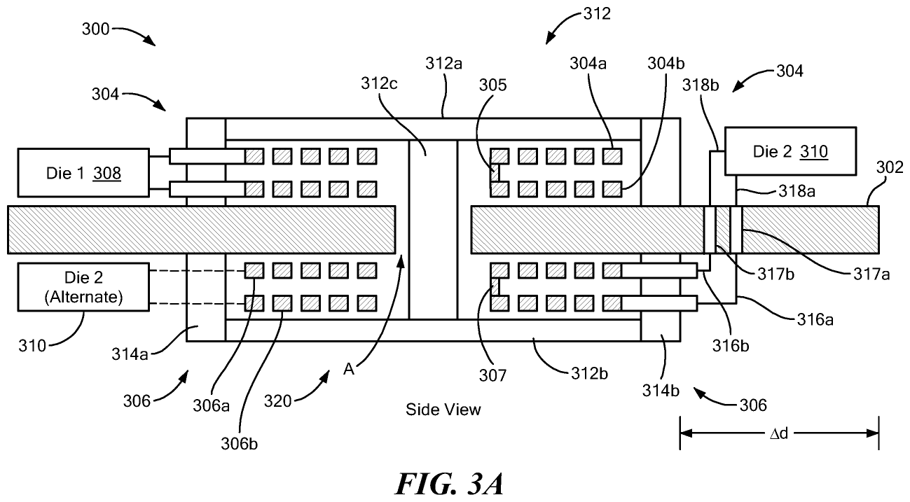

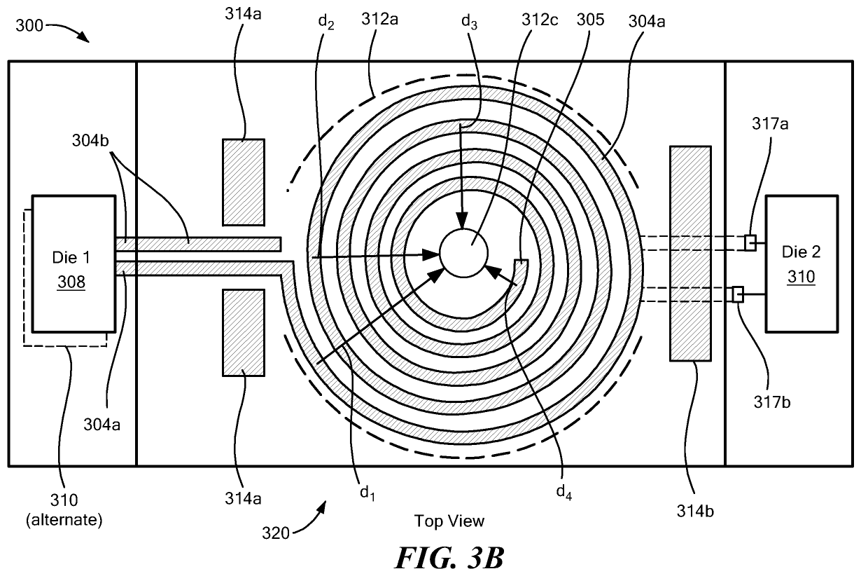

FIGS. 3A-3B show side and top views, respectively, of another example transformer-based isolator 300 with multi-level coils, in accordance with the present disclosure. Isolator 300 can include substrate 302 and first and second coils 304, 306, as shown. Substrate 302 is configured to receive/support first and second semiconductor die 308 and 310. Substrate 302 may have an aperture, A, configured to receive a portion of a transformer core (core) 312. Coils 304, 306 can be configured for coupled operation as a transformer 320 in conjunction with core 312. Core 312 is shown having first and second outer portions 312a-b and central portion 312c. Central core portion 312c is shown passing through substrate aperture A. In some embodiments outer core portions 312a-b may have disc shapes while central core portion 312c may have a cylindrical shape; other shapes for core portions and components are possible within the scope of the present disclosure. First and second coils 304, 306 may be connected to first and second IC dies (die) 308, 310, labeled as “Die 1” and “Die 2,” respectively. Core 312 can also include side (lateral) portions 314a-b, which can abut or connect with core outer portions 312a-b, as shown in FIGS. 3A-3B.

First and second coils 304, 306 are shown having portions on different levels, e.g., first coil portions 304a-b and second coil portions 306a-b, respectively. As shown in FIG. 3B, first coil portion 304a may traverse a path on one level (surface) from a position distal to aperture A, e.g., near or at die 308 or a connection to die 308, to a position adjacent to aperture A, with the path spiraling around aperture A. At via (through hole) 305 first coil portion 304a on one level can be connected to first coil portion 304b on a different level, as shown in FIG. 3A. Similarly, second coil portion 306a may traverse a path on one level (surface) from a position distal to aperture A, e.g., near or at die 310 or a connection to die 310, to a position adjacent to aperture A, with the path spiraling around aperture A. At via (through hole) 307 second coil portion 306a on one level is connected to second coil portion 306b on a different level, as shown in FIG. 3A.

In FIG. 3A, die 308 and 310 are shown on the same side (surface) of substrate 302. Such a configuration may reduce the physical extent (footprint) of the package in a given direction, e.g., height relative to the substrate. As shown, semiconductor die (“Die 2”) 310 may be connected to second coil 306 by suitable connections such as metal connections 316a-b formed in the coil layer to through hole vias 317a-b in substrate 302 and then to wire bonds 318a-b, which connect the through hole vias to the die 310. In alternate embodiments, other suitable connections may be used within the scope of the present disclosure. For example, an alternate position of die 310 is also shown, on the opposite side of substrate 302 as die 308 but in the same or generally the same location (e.g., in azimuth or angular position) relative to aperture A. Such a configuration can allow isolator 300 to occupy a smaller volume or footprint than, e.g., when die 308, 310 are positioned on the same side of substrate 302 and on opposite sides of aperture A (e.g., in azimuth or angular position). The commensurate reduction in width of isolator 300 with die 310 in the alternate position is shown by Ad in FIG. 3A. Similar space savings (smaller footprints) can be achieved by semiconductor (IC) packages including isolator 300 (or a similar isolator) with die 310 in the alternate position/configuration. FIG. 3B also shows that a coil portion (e.g., 304a) does not necessarily have to have a uniformly spiral path (shape); instead, the coil can have any suitable shape traversing/travelling around aperture A, with successive locations along the path having decreasing distances (d1-d4) from a distal location (near die 308 or a connection to die 308) to a location near or adjacent to aperture A and via 305. Coil portion 304b (not shown) on a different level could, likewise, have a path that has any suitable shape traversing/travelling around aperture A, with successive locations along the path having increasing distances (similar d1-d4 but reversed in order, i.e., d4-d1) from a location near aperture A (where 304b and 304a are connected by via 305) to a distal location near die 308.

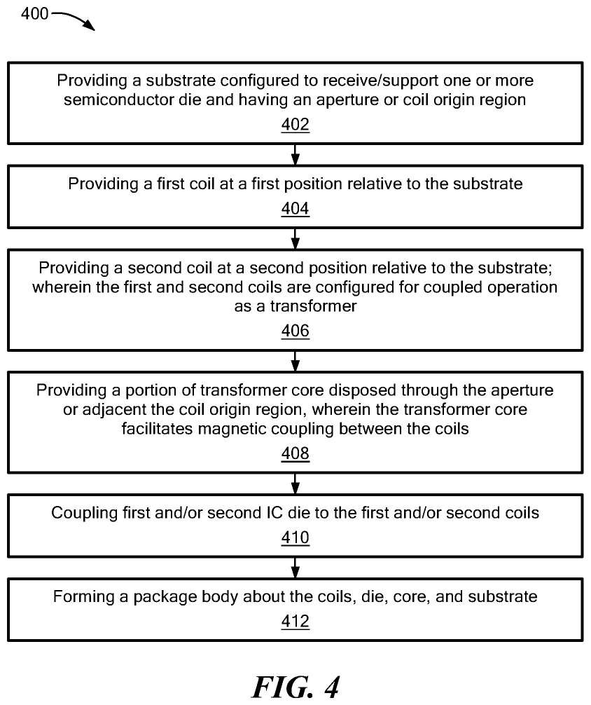

FIG. 4 is a block diagram showing steps in an example fabrication method for a transformer-based isolator 400 with multi-level coils, in accordance with the present disclosure. Method 400 can include providing a substrate configured to receive at least one semiconductor die, as described at 402. The substrate can include of have one or more apertures configured to receive a portion (material or part) of a transformer core. In some embodiments, the substrate and/or a coil structure can include one or more coil origin regions, around which one or more coil or coil portions may be configured (coiled). The substrate can be of any suitable type, including but not limited to, a lead frame (e.g., a molded lead frame), a flexible substrate, a printed circuit board (PCB), a ceramic substrate, e.g., including high-temperature co-fired ceramic (HTCC) and/or low-temperature co-fired ceramic (LTCC), a glass substrate with one or more layers of metal and insulator material, an alumina substrate, a flexible substrate, e.g., polyimide, and the like.

A first coil can be provided at (disposed on) a first coil position or location (e.g., a surface or level) relative to (e.g., a first side of) the substrate, as described at 404. The first coil can have a first coil portion, e.g., on a first level (surface) relative to the substrate, and can have a path from a first location, e.g., at or near a first semiconductor (IC) die at a distal location, to a second location, e.g., adjacent or near to the aperture or coil origin region, as described at 406. The path of the first portion can have a decreasing distance to the aperture or coil origin region along the path. The first coil can have a second coil portion, e.g., on a second level or surface relative to the substrate. The second coil portion may be connected to the first coil portion by a conductive structure, e.g., a via or conductive through hole. The path of the second coil portion of the first coil can have an increasing distance from the second location, e.g., at or near the aperture or coil origin region, as the path travels from the aperture or coil origin region to the first location, e.g., a distal location (relative to the aperture or coil origin region) near the first die or connection with the die.

A second coil can be provided to (disposed on) a second coil position or location (e.g., a different surface or level than used for the first coil) relative to the substrate, e.g., on a second side of the substrate, as described at 406. The second coil can have a first coil portion, e.g., on a first level (surface) relative to the substrate, and can include a path from a first location, e.g., a location at or near a second semiconductor (IC) die, to a second location, e.g., adjacent the aperture or coil origin region. The path of the first portion of the second coil can have a decreasing distance to the aperture or coil origin region along the path. The second coil can have a second coil portion, e.g., on a second level relative to the substrate. The second coil portion of the second coil can be connected to the first coil portion by conductive structure, e.g., a conductive through hole or via. The path of the second coil portion can have an increasing (radial) distance to the aperture or coil origin region, as the path coils around the aperture or coil origin region and travels/traverses from the second location (e.g., at or near the aperture or coil origin region) to the first location (e.g., a location near the second die or connection with the die). The first and second coils can be configured for coupled operation as a transformer. Insulator material can be placed/formed between the first and second coils (and their first and second coil portions) to prevent shorting and to facilitate galvanic isolation, a.k.a., voltage isolation.

A portion of a transformer (magnetic) core can be disposed in or through the aperture in the substrate, as described at 408. In other embodiments, the core does not extend through (or completely through) the aperture. For example, a core (having one or more core components or portions) may be disposed above and/or below the first and/or second coils, e.g., on a side of a coil distal to the substrate. First and second semiconductor (IC) die can be coupled to the first and second coils, as described at 410. The physically separated first and second coils can provide galvanic separation to integrated circuits (ICs) of the first and second die during operation of the transformer formed by the coils with the core. Any suitable material may be used for the core. In some examples, a soft ferromagnetic material, e.g., ferrite, may be used for the core. In some embodiments, the ferromagnetic core or portions of the core may be formed by a molding process or multiple molding processes, or by an electroplating or electrodeposition process. A body, e.g., a package body, can be formed, as described at 412. A package body can be formed by an over-molding step, in some examples and/or embodiments, by applying a mold material (compound) to the coils, semiconductor (IC) die, and core, and the substrate, e.g., PCB, lead frame, etc. In some embodiments, the core (or one or more portions of the core) may be molded before the die are coupled to the coils, or after the package body is molded.

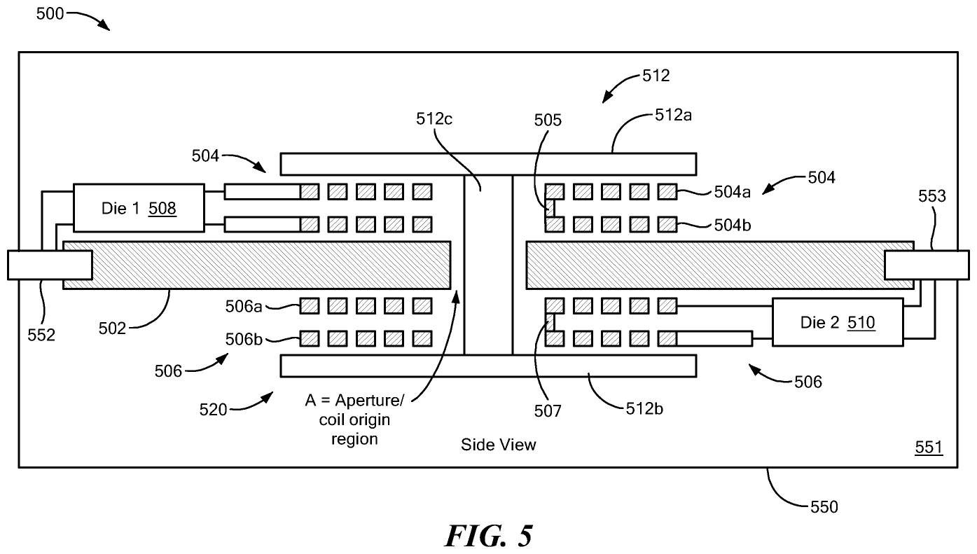

FIG. 5 shows a side view of an example IC package 500 having a transformer-based isolator with multi-level coils, in accordance with the present disclosure. Package 500 can include substrate 502 and first and second coils 504, 506, as shown. Substrate 502 is configured to receive/support first and second semiconductor (IC) die 508 and 510 labelled as “Die 1” and “Die 2,” respectively. Die 508 and die 510 are shown disposed on opposite sides of substrate 502. Substrate 502 may have an aperture, A, configured to receive a portion of a transformer core 512. Coils 504, 506 can be configured for coupled operation as a transformer 520 in conjunction with core 512. Core 512 is shown having first and second outer portions 512a-b and central portion 512c. Central core portion 512c is shown passing through substrate aperture A. Package 500 also includes package body 550 and may include lead sets 552 and 553 for connection to external circuits, systems, and/or components. Lead sets 552 and 553 may each include two or more leads and may be connected to die 508 and 510, respectively. The connection to the die may include but is not limited to wire bonding, conductive bumps, pillars, or other electrical connections. Package body may include dielectric material 551, e.g., mold compound and/or other insulator material(s), for protection and/or insulation of internal components. As noted previously, in some embodiments central core portion 512c may be omitted/absent, in which case “A” may indicate a coil origin region; in some such embodiments, an aperture may be omitted from substrate 502.

First and second coils 504, 506 may have portions on different levels, e.g., as shown by first coil portions 504a-b and second coil portions 506a-b, respectively. As shown in FIG. 5B, first coil portion 504a may traverse a path on one level (surface) from a position distal to aperture A to a position adjacent to aperture A, with the path spiraling around aperture A. At via (through hole) 505 first coil portion 504a on one level is connected to first coil portion 504b on a different level, as shown in FIG. 5A. Similarly, second coil portion 506a may traverse a path on one level (surface) from a position distal to aperture A to a position adjacent to aperture A, with the path spiraling around aperture A. At via 507 second coil portion 506a on one level is connected to second coil portion 506b on a different level, as shown in FIG. 5A.

Embodiments of the present disclosure can be configured or fabricated to have separation distances between conductive parts to obtain or meet desired voltage isolation requirements or criteria, e.g., creepage, voltage breakdown, and/or voltage clearance requirements. For example, package 500 (or other embodiments/aspects according to the present disclosure) can be fabricated so that two conductors/conductive components are spaced apart from other package features/components by a desired distance. For example, lower (second) portion of first coil 504b and upper (first) portion of second coil 506a (on opposite sides of substrate 502) can be fabricated to be separated/spaced apart by a desired distance. For further example, depending on any desired isolation voltage requirement(s) for package 500 in a given application, the distance between any two conductive components, circuit portions, or voltage regions of the primary and secondary sides of transformer 520, e.g., coil portion 504b and coil portion 506a, can be or can be at least 1 mm, 1.2 mm, 1.4 mm, 2 mm, 3.9 mm, 4 mm, 6 mm, 7.2 mm, 8 mm, 10 mm, or more, within the scope of the present disclosure. Of course, the foregoing numerical values are illustrative, and packages/isolators and modules may be fabricated/implemented with other distances between components within the scope of the present disclosure. In some embodiments, package 500 (or a similar package) can be fabricated or configured to have a desired separation distance between certain conductive parts/components/features and other parts/components/features, including exposed portions of leads or lead sets, e.g., a separation distance of 7.2 mm, 8 mm, 8.2 mm, 8.5 mm, 10 mm, or more, to meet internal creepage, voltage breakdown, and/or external clearance requirements for a given pollution degree rating as defined by certain safety standards bodies such as the Underwriters Laboratories (UL) and/or the International Electrotechnical Commission (IEC).

In some embodiments and examples, a dielectric material (e.g., gel) may be used for potting and/or protecting PCB systems, structures, and/or assemblies, e.g., voltage-isolated semiconductor packages or modules, to protect die (dies) and/or interconnects from environment conditions and/or to provide dielectric insulation. In some examples and embodiments, a dielectric gel may be used to coat the die, wire bonds, or transformer prior to molding the package with mold compound 551 to form the package body 550. In some examples, a dielectric material may include, but is not limited to, one or more of the following materials: DOWSIL™ EG-3810 Dielectric Gel (made available by The Dow Chemical Corporation, a.k.a., “Dow”, and DOWSIL™ EG-3896 Dielectric Gel (made available by Dow), which has the ability to provide isolation greater than 20 kV/mm. Other suitable gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments of the inventive subject matter can afford various benefits relative to prior art techniques. For example, embodiments and examples of the present disclosure can enable or facilitate use of smaller size packages or footprints for a given power or voltage rating, including for given voltage isolation requirements such as creepage and/or clearance. Embodiments and examples of the present disclosure can enable or facilitate lower costs and higher scalability for manufacturing of IC packages/modules having voltage-isolated IC die and transformers.

Various embodiments of the concepts, systems, devices, structures, and techniques sought to be protected are described above with reference to the related drawings. Alternative embodiments can be devised without departing from the scope of the concepts, systems, devices, structures, and techniques described. For example, a transformer may be built on one side of a substrate, e.g., with the transformer including four or more (4+) layers or metal to form the two coils, each having two or more (2+) layers. Further, while some examples are described herein as having transformer cores or core portions aligned in a direction normal to the substrate other examples and/or embodiments may have a core or core portions aligned in other directions, e.g., parallel to the substrate. For further example, in some embodiments transformer windings (coils) may have different numbers of turns, which may include a whole number or fractional number of turns, e.g., 1.5, 2.5, 1.75, 1.8, 2.25, etc. In some embodiments/examples, to lower capacitive coupling to the coil from the core, one or more portions, e.g., the upper and/or lower core portions, may be shaped. In some cases, the upper and/or lower core portions may have portions/regions removed (or not formed/produced) such that a wedge/sector of material, e.g., from 10 to 11, 1 to 2, 4 to 5 and 7 to 8 on a clock face, would be missing; other shapes of such removed/omitted regions/sectors are also possible.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration. Any embodiment or design described as “exemplary” is not necessarily to be construed as preferred or advantageous over other embodiments or designs. The terms “one or more” and “at least one” indicate any integer number greater than or equal to one, i.e., one, two, three, four, etc.; though, where context admits, those terms may indicate fractional values. The term “plurality” indicates any integer number greater than one. The term “connection” can include an indirect “connection” and a direct “connection.”

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed, but are used merely as labels to distinguish one claim element having a certain name from another element having a same name (but for use of the ordinal term) to distinguish the claim elements.

The terms “approximately” and “about” may be used to mean within +20% of a target (or nominal) value in some embodiments, within plus or minus (+) 10% of a target value in some embodiments, within +5% of a target value in some embodiments, and yet within +2% of a target value in some embodiments. The terms “approximately” and “about” may include the target value. The term “substantially equal” may be used to refer to values that are within +20% of one another in some embodiments, within +10% of one another in some embodiments, within +5% of one another in some embodiments, and yet within +2% of one another in some embodiments.

The term “substantially” may be used to refer to values that are within +20% of a comparative measure in some embodiments, within +10% in some embodiments, within +5% in some embodiments, and yet within +2% in some embodiments. For example, a first direction that is “substantially” perpendicular to a second direction may refer to a first direction that is within +20% of making a 90° angle with the second direction in some embodiments, within +10% of making a 90° angle with the second direction in some embodiments, within +5% of making a 90° angle with the second direction in some embodiments, and yet within +2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A voltage-isolated integrated circuit (IC) package comprising:
a substrate including an aperture;
first and second semiconductor die disposed on the substrate;
first and second lead sets connected to the first and second semiconductor die, respectively;
a transformer configured to provide magnetic coupling and galvanic separation between the first and second semiconductor die, the transformer having,
(i) a first coil disposed on a first surface of the substrate and coupled to the first semiconductor die, wherein the first coil has a first coil portion on a first level with respect to the first surface of the substrate and includes a path from a location distal to the aperture to a location adjacent the aperture, the first coil portion having a decreasing radial distance to the aperture along the path, wherein the path of the first coil portion extends around the aperture;
(ii) a second coil disposed on a second surface of the substrate and coupled to the second semiconductor die, wherein the second coil has a first coil portion on a first level with respect to the second surface of the substrate and includes a path from a location distal to the aperture to a location adjacent the aperture, the first coil portion having a decreasing radial distance to the aperture along the path, wherein the path of the first coil portion extends around the aperture; and
(iii) a soft ferromagnetic core disposed adjacent to the first coil and/or second coil; and
a mold material forming a package body and configured to cover a portion of the substrate, core, and first and second coils, wherein the package body includes a plurality of apertures exposing portions of the first and second lead sets.

2. The voltage-isolated IC package of claim 1, wherein a portion of the core is disposed through the aperture in the substrate.

3. The voltage-isolated IC package of claim 1, wherein a first portion of the core is disposed on a side of the first coil distal to the substrate.

4. The voltage-isolated IC package of claim 3, wherein a second portion of the core is disposed on a side of the second coil distal to the substrate.

5. The voltage-isolated IC package of claim 1, wherein the first coil further comprises a second coil portion on a second level with respect to the first surface of the substrate and includes a path from the location adjacent the aperture to the location distal to the aperture, the second coil portion having an increasing radial distance to the aperture along the path, wherein the second coil portion is connected to the first coil portion, and wherein the path of the second coil portion extends around the aperture.

6. The voltage-isolated IC package of claim 1, wherein the second coil further comprises a second coil portion on a second level with respect to the second surface of the substrate and includes a path from the location adjacent the aperture to the position distal to the aperture, the second coil portion having an increasing radial distance to the aperture along the path, wherein the second coil portion is connected to the first coil portion, and wherein the path of the second coil portion extends around the aperture.

7. The voltage-isolated IC package of claim 1, wherein the first or second coil comprises elliptical windings.

8. The voltage-isolated IC package of claim 7, wherein the first or second coil comprises circular windings.

9. The voltage-isolated IC package of claim 1, wherein the first or second coil comprises rectangular windings.

10. The voltage-isolated IC package of claim 9, wherein the first or second coil comprises square-like windings.

11. The voltage-isolated IC package of claim 1, wherein the substrate comprises a flexible substrate.

12. The voltage-isolated IC package of claim 1, wherein the substrate comprises a printed circuit board (PCB).

13. The voltage-isolated IC package of claim 1, wherein the substrate comprises a low-temperature cofired ceramic (LTCC) or a high-temperature cofired ceramic (HTCC).

14. The voltage-isolated IC package of claim 1, wherein the substrate comprises an alumina substrate.

15. The voltage-isolated IC package of claim 1, wherein the substrate comprises a glass substrate comprising one or more layers of metal and insulator.

16. The voltage-isolated IC package of claim 1, wherein the substrate comprises a lead frame.

17. The voltage-isolated IC package of claim 16, wherein the lead frame comprises a molded lead frame.

18. The voltage-isolated IC package of claim 1, further comprising a dielectric material covering a portion of the transformer, first coil, and/or second coil.

19. The voltage-isolated IC package of claim 18, wherein the dielectric material comprises a gel.

20. The voltage-isolated IC package of claim 1, wherein a shortest distance between first and second voltage regions of primary and secondary sides of the transformer, respectively, is at least 1 mm.

21. The voltage-isolated IC package of claim 1, wherein a shortest distance between first and second voltage regions of primary and secondary sides of the transformer, respectively, is at least 1.2 mm.

22. The voltage-isolated IC package of claim 1, wherein a shortest distance between first and second voltage regions of primary and secondary sides of the transformer, respectively, is at least 1.5 mm.

23. The voltage-isolated IC package of claim 1, wherein a shortest distance between first and second voltage regions of primary and secondary sides of the transformer, respectively, is at least 3 mm.

24. The voltage-isolated IC package of claim 1, wherein a shortest distance between first and second voltage regions of primary and secondary sides of the transformer, respectively, is at least 5.5 mm.

25. The voltage-isolated IC package of claim 1, wherein a shortest distance between first and second voltage regions of primary and secondary sides of the transformer, respectively, is at least 7.2 mm.

26. The voltage-isolated IC package of claim 1, wherein a shortest distance between exposed portions of the first and second lead sets, respectively, is at least 8 mm.

27. The voltage-isolated IC package of claim 1, wherein the first or second semiconductor die comprises a gate driver.

28. A method of making a voltage-isolated integrated circuit (IC) package, the method comprising:
(i) providing a substrate, wherein the substrate includes an aperture;
(ii) providing a portion of a transformer core in the aperture;
(iii) providing first and second semiconductor die disposed on the substrate;
(iv) providing a first coil disposed on a first surface of the substrate and coupled to the first semiconductor die, wherein the first coil has a first coil portion on a first level with respect to the first surface of the substrate, the first coil portion including a path from a location distal to the aperture to a location adjacent the aperture and having a decreasing radial distance to the aperture along the path; and
(v) providing a second coil disposed on a second surface of the substrate and coupled to the second semiconductor die, wherein the second coil has a first coil portion on a first level with respect to the second surface of the substrate, the first coil portion including a path from a location distal to the aperture to a location adjacent the aperture and having a decreasing radial distance to the aperture along the path.

29. The method of claim 28, further comprising providing a second coil portion of the first coil on a second level with respect to the first surface of the substrate, the second coil portion including a path from the location adjacent the aperture to the location distal to the aperture, wherein the second coil portion has an increasing radial distance to the aperture along the path, and wherein the first coil portion is connected to the second coil portion.

30. The method of claim 29, further comprising connecting the first coil portion of the first coil to the second coil portion by a via.

31. The method of claim 28, further comprising providing a second coil portion of the second coil on a second level with respect to the second surface of the substrate, the second coil portion including a path from the location adjacent the aperture to the location distal to the aperture, wherein the second coil portion has an increasing radial distance to the aperture along the path, and wherein the first coil portion is connected to the second coil portion.

32. The method of claim 31, further comprising connecting the first coil portion of the second coil to the second coil portion by a via.

33. The method of claim 28, wherein the first and second coils and the transformer core are configured as a transformer for magnetically coupling the first semiconductor die to the second semiconductor die.

34. The method of claim 28, wherein the substrate comprises a flexible substrate.

35. The method of claim 28, wherein the substrate comprises a printed circuit board (PCB).

36. The method of claim 28, wherein the substrate comprises a low-temperature cofired ceramic (LTCC) or a high-temperature cofired ceramic (HTCC).

37. The method of claim 28, wherein the substrate comprises an alumina substrate.

38. The method of claim 28, wherein the substrate comprises a glass substrate comprising one or more layers of metal and insulator.

39. The method of claim 28, wherein the substrate comprises a lead frame.

40. The method of claim 39, wherein the lead frame comprises a molded lead frame.

41. A voltage-isolated integrated circuit (IC) package comprising:
a substrate);
one or more semiconductor die disposed on the substrate;
one or more lead sets configured for connection to the one or more semiconductor die, respectively;
a transformer configured to provide magnetic coupling and galvanic separation for circuitry including the one or more semiconductor die, the transformer having,
(i) a first spiral coil disposed on a first level with respect to the substrate and extending around a coil origin region;
(ii) a second spiral coil disposed on a second level with respect to the substrate and extending around the coil origin region; and
(iii) a soft ferromagnetic core having a portion disposed adjacent the first spiral coil or second spiral coil; and
a package body configured to cover a portion of the substrate, the ferromagnetic core, and the first and second spiral coils, wherein the package body includes a plurality of apertures exposing portions of the one or more lead sets.

42. The voltage-isolated IC package of claim 41, wherein the coil origin region comprises an aperture disposed through the substrate.

43. The voltage-isolated IC package of claim 42, wherein the first spiral coil comprises a first coil portion disposed on the first level, the first coil portion including a path from a location distal to the aperture to a location adjacent the aperture and having a decreasing radial distance to the aperture along the path.

44. The voltage-isolated IC package of claim 43, wherein the first spiral coil further comprises a second coil portion disposed on a third level with respect to the substrate, the second coil portion including a path from the location adjacent the aperture to the position distal to the aperture and having an increasing radial distance to the aperture along the path, wherein the second coil portion is connected to the first coil portion of the first spiral coil.

45. The voltage-isolated IC package of claim 42, wherein the second spiral coil comprises a first coil portion disposed on the second level, the first coil portion including a path from a location distal to the aperture to a location adjacent the aperture and having a decreasing radial distance to the aperture along the path.

46. The voltage-isolated IC package of claim 45, wherein the second spiral coil further comprises a second coil portion on a fourth level with respect to the substrate, the second coil portion including a path from the location adjacent the aperture to the position distal to the aperture and having an increasing radial distance to the aperture along the path, wherein the second coil portion is connected to the first coil portion of the second spiral coil.

47. The voltage-isolated IC package of claim 42, wherein at least a portion of the ferromagnetic core is disposed in the aperture.

48. The voltage-isolated IC package of claim 41, where the one or more semiconductor die comprise first and second semiconductor die connected to the first spiral coil and the second spiral coil, respectively.
